(19) United States
(12) Patent Application Publication
(10) Pub. No.: US 2025/0171900 A1
(43) Pub. Date: May 29, 2025

(54) PROCESS GAS RECYCLING

(71) Applicant: ASM IP Holding B.V., Almere (NL)

(72) Inventors: Ivo Johannes Raaijmakers, Amersfoort (NL); Eric James Shero, Phoenix, AZ (US); Giuseppe Alessio Verni, Ismaning (DE); Matthew Surman, Helsinki (FI); Michael Eugene Givens, Oud-Heverlee (BE); Charles Dezelah, Helsinki (FI)

(21) Appl. No.: 18/963,319

(22) Filed: Nov. 27, 2024

Related U.S. Application Data
(60) Provisional application No. 63/603,964, filed on Nov. 29, 2023.

(51) Int. Cl. C23C 16/455; B01D 3/14; B01D 8/00; B01D 53/02; C23C 16/44; C23C 16/52

(52) U.S. Cl. CPC C23C 16/45561; B01D 3/143; B01D 8/00; B01D 53/02; C23C 16/4408; C23C 16/4412; C23C 16/45527; C23C 16/52; B01D 2258/0216

(57) ABSTRACT

Described herein are systems and methods that may be useful in the context of gas reuse thin film deposition equipment. Embodiments of the present disclosure are particularly related to one or more of separate collection and recycling one or more gasses such as precursors, reactants, and purge gasses.

### CROSS-REFERENCE TO RELATED APPLICATION(S)

This Application claims the benefit of U.S. Provisional Application 63/603,964 filed on Nov. 29, 2023, the entire contents of which are incorporated herein by reference.

### FIELD OF INVENTION

The embodiments of the present disclosure are in the field of vapor phase thin film processing. They are particularly related to gas recycling in thin film processing.

### BACKGROUND OF THE DISCLOSURE

Thin film processing techniques such as chemical vapor deposition, atomic layer deposition, and etches such as atomic layer etch consume large quantities of gasses and vapors including precursors, reactants, and inert gasses. This holds both for thermal processes and their plasma-enhanced variants.

Not all precursor may be consumed during a thin film process. Therefore, there is an opportunity for precursor recycling.

Not all reactant may be consumed during thin film processing. Therefore, there is an opportunity for reactant recycling.

Inert process gasses may be substantially unchanged by thin film processes. Therefore, there is an opportunity for inert process gas recycling.

### SUMMARY OF THE DISCLOSURE

In one embodiment, described herein is a system comprising a reaction chamber; a precursor source comprising a precursor, the precursor source being operationally connected to the reaction chamber by means of a precursor line, the precursor line being disposed with a precursor valve that is operable to open and close the precursor line; a reactant source comprising a reactant, the reactant source being operationally connected to the reaction chamber by means of a reactant line, the reactant line being disposed with a reactant valve that is operable to open and close the reactant line; a precursor side stream line that is constructed and arranged to remove a precursor side stream from the reaction chamber, the precursor side stream line being disposed with a precursor side stream valve that is operable to open and close the precursor side stream line; a reactant side stream line that is constructed and arranged to remove a reactant side stream from the reaction chamber, the reactant side stream line being disposed with a reactant side stream valve that is operable to open and close the reactant side stream line.

In some embodiments, the system further comprises a controller, the controller comprising a memory containing computer-readable instructions which, when executed, cause the system to open the precursor line, close the reactant line, open the precursor side stream line, and close the reactant side stream line.

In some embodiments, the system further comprises a controller, the controller comprising a memory containing computer-readable instructions which, when executed, cause the system to open the reactant line, close the precursor line, open the reactant side stream line, and close the precursor side stream line.

In some embodiments, the system further comprises a controller, the controller comprising a memory containing computer-readable instructions which, when executed, cause the system to execute a cyclical deposition process, the cyclical deposition process comprising a plurality of cycles, ones from the plurality of cycles comprising a precursor pulse and a reactant pulse; wherein the precursor pulse comprises opening the precursor line, closing the reactant line, opening the precursor side stream line, and closing the reactant side stream line, thereby providing the precursor to the reaction chamber and removing the precursor side stream from the reaction chamber via the precursor side stream line; and, wherein the reactant pulse comprises opening the reactant line, closing the precursor line, opening the reactant side stream line, and closing the precursor side stream line, thereby providing the reactant to the reaction chamber and removing the reactant side stream from the reaction chamber via the reactant side stream line.

In some embodiments, the system further comprises a purge gas source comprising a purge gas, the purge gas source being operationally connected to the reaction chamber by means of a purge gas line, the purge gas line being disposed with one or more purge gas valves that are operable to open and close the purge gas line.

In some embodiments, the cyclical deposition process further comprises a post precursor purge and a post reactant purge, the post precursor purge being executed after the precursor pulse, wherein the post precursor purge comprises opening the purge gas line, opening the precursor side stream line, closing the precursor line, closing the reactant line, and closing the reactant side stream line; the post reactant purge being executed after the reactant pulse, wherein the post reactant purge comprises opening the purge gas line, opening the reactant side stream line, closing the precursor line, closing the reactant line, and closing the precursor side stream line.

In some embodiments, the precursor side stream line is operationally connected to a precursor trap, the precursor trap being constructed and arranged for removing unreacted precursor from the precursor side stream.

In some embodiments, the reactant side stream line is operationally connected to a reactant trap, the reactant trap being constructed and arranged for removing unreacted reactant from the reactant side stream.

In some embodiments, the system further comprises a purge gas recuperation unit, and a recuperated purge gas line, the purge gas recuperation unit being constructed and arranged for recovering used purge gas from at least one of the reactant side stream and the precursor side stream, thereby obtaining a recuperated purge gas stream; the recuperated purge gas line operationally connecting the purge gas recuperation unit to the purge gas source, to recycle purge gas.

In some embodiments, the purge gas comprises at least one of N₂, H₂, and a noble gas.

In some embodiments, the precursor trap comprises a cold trap.

In some embodiments, the system further comprises a collection well constructed and arranged for holding unreacted precursor that was trapped by the cold trap.

In some embodiments, the precursor trap comprises a sorption trap.

In some embodiments, the system further comprises a fractional distillation device, the fractional distillation device being constructed and arranged for purifying unreacted precursor from the precursor trap, thereby obtaining a purified precursor stream.

In some embodiments, the fractional distillation device is operationally connected with the precursor source to provide at least a part of the purified precursor stream to the precursor source.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a system 100 according to an embodiment of the present disclosure.

FIG. 2 shows an embodiment of a method as described herein.

FIG. 3 shows an embodiment of a purge gas recuperation unit 300 as described herein.

FIG. 4 shows an embodiment of a system 400 according to an embodiment of the present disclosure.

FIG. 5 shows an embodiment of a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof.

The term “deposition process” as used herein can refer to the introduction of precursors (and/or reactants) into a reaction chamber to deposit a layer over a substrate. “Cyclical deposition processes” are examples of “deposition processes”. Deposition processes can comprise forming a solid reaction product starting from gaseous precursors and reactants.

The term “cyclical deposition process” can refer to a sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. A cyclical deposition process may or may not comprise self-limiting surface reactions.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), molecular layer deposition (MLD), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the adsorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reactor chamber in between two pulses of gasses which react with each other. For example, a purge, e.g. using nitrogen gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

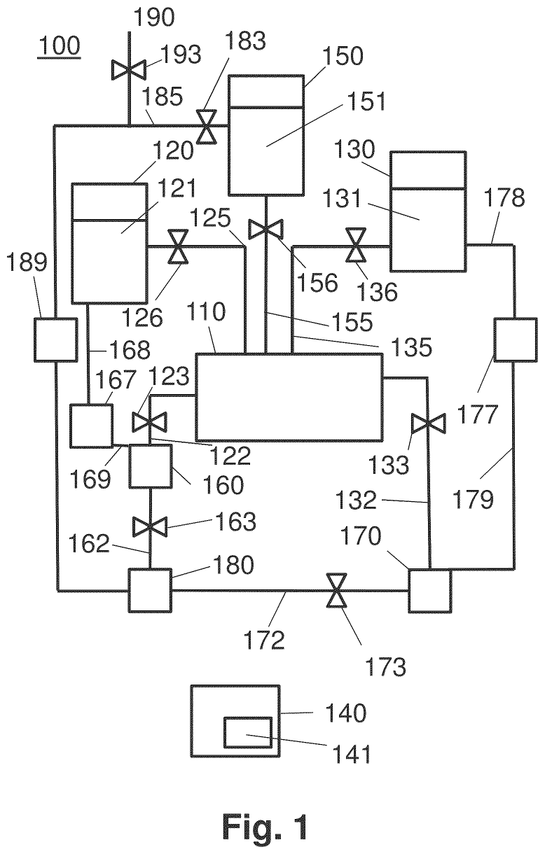

Referring to FIG. 1, described herein is an embodiment of a system 100 according to the present disclosure. The system 100 comprises a reaction chamber 110. The system 100 further comprises a precursor source 120. The precursor source comprises a precursor 121. The precursor source 120 is operationally connected to the reaction chamber 110 by means of a precursor line 125. Note that the term “line” as used herein may be used interchangeably with the word “tube”. The precursor line 125 is disposed with a precursor valve 126 that is operable to open and close the precursor line 125. The system 100 further comprises a reactant source 130. The reactant source comprises a reactant 131. The reactant source 130 is operationally connected to the reaction chamber 110 by means of a reactant line 135. The reactant line 135 is provided with a reactant valve 136 that is operable to open and close the reactant line 135. The system 100 further comprises a precursor side stream line 122. The precursor side stream line 122 is constructed and arranged to remove a precursor side stream from the reaction chamber 110. The precursor side stream line 122 is provided with a precursor side stream valve 123 that is operable to open and close the precursor side stream line 122. The system 100 further comprises a reactant side stream line 132. The reactant side stream line 132 is constructed and arranged to remove a reactant side stream from the reaction chamber. The reactant side stream line 132 is provided with a reactant side stream valve 133 that is operable to open and close the reactant side stream line.

The system 100 can further comprise a controller 140. The controller 140 can comprise a memory 141. The memory can comprise computer-readable instructions which, when executed, cause the system to open the precursor line 125, close the reactant line 135, open the precursor side stream line 122, and close the reactant side stream line 122. Thus, precursor can be captured during a precursor pulse and optionally during a subsequent purge. By capturing precursor and reactant separately, precursor and/or reactant can be recycled or treated more easily. It shall be understood that the precursor line 125 can be opened by opening the precursor valve 126. It shall be understood that the reactant line 135 can be closed by closing the reactant valve 136. It shall be understood that the precursor side stream line 122 can be opened by opening the precursor side stream valve 123. It shall be understood that the reactant side stream line 132 can be closed by closing the reactant side stream valve 133.

Additionally or alternatively, and in some embodiments, the memory 141 can comprise computer-readable instructions which, when executed, cause the system to open the reactant line 135, close the precursor line 125, open the reactant side stream line 132, and close the precursor side stream line 122. Thus, reactant and reactant by products can be captured during a reactant pulse, and optionally during a subsequent purge. It shall be understood that the reactant line 135 can be opened by opening the reactant valve 136. It shall be understood that the precursor line 125 can be closed by closing the precursor valve 126. It shall be understood that the reactant side stream line 132 can be opened by opening the reactant side stream valve 133. It shall be understood that the precursor side stream line 122 can be closed by closing the precursor side stream valve 123.

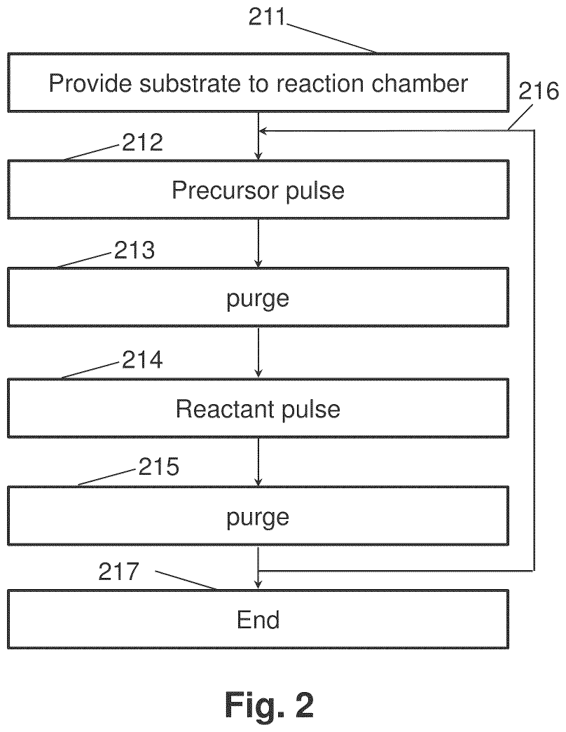

Additionally or alternatively, and in some embodiments, the memory 141 can comprise computer-readable instructions which, when executed, cause the system to execute a cyclical deposition process, an embodiment of which is illustrated by means of FIG. 2. The method illustrated by FIG. 2 comprises a step 211 of positioning a substrate on a substrate support comprised in a reaction chamber. Then, the method comprises executing a cyclical vapor phase deposition process that comprises repeatedly executing a plurality of cycles 216. Ones from the plurality of cycles comprise a precursor pulse 212 and a reactant pulse 214. Subsequent precursor pulses 212 and reactant pulses 214 are separated by purges 213,215 to prevent gas phase mixing between precursor and reactant. The purge 213 that occurs after the precursor pulse 212 can be called a post precursor purge 213. The purge 215 that occurs after the reactant pulse 214 can be called a post reactant purge 215.

In some embodiments, the controller can comprise computer-readable instructions which, when executed, cause the system to actuate various pulsing valves and outlet valves with some time delay to allow for the time it takes for various gasses to flow from their source to the respective side stream lines. The time delay can be, for example, from at least 10 ms to at most 1 s, e.g. 100 ms. Outlet valves include the reactant side stream valve 133 and the precursor side stream valve 123. Pulsing valves include the reactant valve 136 and the precursor valve 126.

The precursor pulses 212 comprise exposing the substrate to a precursor, such as a metal precursor. This can be done by opening the precursor line, closing the reactant line, opening the precursor side stream line, and closing the reactant side stream line which causes the precursor to be provided to the reaction chamber, and it causes removal of a precursor side stream from the reaction chamber via the precursor side stream line.

The reactant pulses 214 comprise exposing the substrate to a reactant, such as an oxygen reactant such as oxygen or a nitrogen reactant such as ammonia. This can be done by opening the reactant line, closing the precursor line, opening the reactant side stream line, and closing the precursor side stream line. This causes the reactant to be provided to the reaction chamber and it causes removal of the reactant side stream from the reaction chamber via the reactant side stream line. Thus, the precursor side stream and reactant side stream can be separated, which allows for better abatement of and/or recycling of precursor and/or reactant.

The cyclical deposition process 216 can be carried out until a material having a desired thickness has been deposited. After a material having a desired thickness has been deposited, the method ends 217. Of course, one or more of the cycles can optionally comprise further pulses such as one or more further precursor pulses and one or more further reactant pulses which, in turn, can be separated from other reactant and precursor pulses by purges.

In order to facilitate the purges 213,215, a system 100 according to an embodiment of the present disclosure can further comprise a purge gas source 150. The purge gas source 150 can comprise a purge gas 151. The purge gas source 150 can be operationally connected to the reaction chamber 110 by means of a purge gas line 155. The purge gas line 155 is disposed with one or more purge gas valves 156 that are operable to open and close the purge gas line 155.

During a post precursor purge 213, unreacted precursor can be gradually removed from the reaction chamber 110. During a post reactant purge 215, unreacted reactant can be gradually removed from the reaction chamber 110. This unreacted precursor and unreacted reactant can be advantageously collected separately using embodiments of the present disclosure. In particular, the post precursor purge can comprise opening the purge gas line 155, opening the precursor side stream line 122, closing the precursor line 125, closing the reactant line 135, and closing the reactant side stream line 132. It shall be noted that the purge gas line 155 can be opened with the purge gas valve, that the precursor side stream line 122 can be opened with the precursor side stream valve 123, that the precursor line 125 can be closed with the precursor valve 126, that the reactant line 135 can be closed with the reactant valve 136, and that the reactant side stream line 132 can be closed with the reactant side stream valve 133. Similarly, a post reactant purge 215 can comprise opening the purge gas line 135, e.g. by means of the purge gas valve 136; opening the reactant side stream line 132, e.g. by means of the reactant side stream valve 133; closing the precursor line 125, e.g. by means of the precursor valve 126; closing the reactant line 135, e.g. by means of the reactant valve 136; and, closing the precursor side stream line 122, e.g. by means of the precursor side stream valve 123. Thus, separation of precursor and reactant side streams can be achieved which can allow for better abatement and/or recycling of at least one of precursor and reactant.

In some embodiments, the precursor side stream line 122 is operationally connected to a precursor trap 160. The precursor trap 160 can be constructed and arranged for removing unreacted precursor from the precursor side stream. Thus, precursor can be recovered, which is advantageous. Indeed, in semiconductor deposition equipment such as atomic layer deposition equipment or plasma-enhanced atomic layer deposition equipment, a significant proportion of the precursors used can be wasted, since only a small fraction of the precursor is used during a pulse. By capturing precursor in a precursor trap 160, such as a cold trap or a sorption trap, precursor waste can be countered.

For example, a cold trap can cause reactive gasses such as precursor and ALD by-products to condense or deposit thereon, thereby removing them from the precursor side stream. For example, a sorption trap can absorb and/or adsorb reactive gasses such as precursor and ALD by-products to remove them from the precursor side stream.

In some embodiments, the system 100 comprises multiple precursor traps 160, e.g. 2, 3, 4, 5, 6, or more precursor traps 160. The multiple precursor traps 160 can be arranged in series, in parallel, or in a mixed configuration comprising both series and parallel arrangements. Multiple precursor traps 160 can enhance precursor capture, or enhance the purity of the captured precursor, for example by a purification technique such as fractional condensation.

In some embodiments, captured precursor can be further purified, e.g. by means of fractional distillation. Precursor purification can be done in-situ, e.g. in a system according to an embodiment of the present disclosure. Alternatively, it can be done in the vicinity of the system. Alternatively, precursor purification can be done off-site.

Materials captured by the precursor trap 160 can either be stored in the precursor trap itself, or they can be removed by a particular kind of removal device such as a drain. Additionally or alternatively, and in some embodiments, the system 100 can further comprise a collection well constructed and arranged for holding unreacted precursor that was trapped by the cold trap.

Materials captured by the precursor trap 160 can, in some embodiments, be treated and made harmless in an abatement unit (not shown), which can be part of the presently described system 100, or it can be located elsewhere, e.g. on-site or off-site. Alternatively, materials captured by the precursor trap 160 can be provided to a precursor purification unit 167 The precursor purification unit 167 can be provided with a recuperated precursor pump (not shown) to pump purified precursor to the precursor source 120. The precursor purification unit 167 can be operationally connected to the precursor trap 160 by means of a trapped precursor line 169. The precursor purification unit 167 can be operationally connected to the precursor source 120 by means of a purified precursor line 168 that is constructed and arranged to provide purified precursor from the precursor purification unit 167 to the precursor source 120. For example, the precursor purification unit 167 can comprise a fractional distillation device. The fractional distillation device can be constructed and arranged for purifying unreacted precursor from the precursor trap. Thus, a purified precursor stream can be obtained. In some embodiments, the fractional distillation devices is operationally connected with the precursor source to provide at least a part of the purified precursor stream to the precursor source.

In some embodiments, the reactant side stream line 132 is operationally connected to a reactant trap 170. The reactant trap 170 can be constructed and arranged for removing unreacted reactant from the reactant side stream. Thus, reactant can be recovered, which is advantageous. Indeed, in semiconductor deposition equipment such as atomic layer deposition equipment or plasma-enhanced atomic layer deposition equipment, a significant proportion of the reactants used can be wasted, since only a small fraction of the reactant is used during a pulse. By capturing reactant in a reactant trap 170, such as a cold trap or a sorption trap, reactant waste can be countered. In some embodiments, captured reactant can be further purified, e.g. by means of fractional distillation. Reactant purification can be done in-situ, e.g. in a system according to an embodiment of the present disclosure. Alternatively, it can be done in the vicinity of the system. Alternatively, reactant purification can be done off-site.

In some embodiments, the system 100 comprises multiple reactant traps 170, e.g. 2, 3, 4, 5, 6, or more reactant traps 170. The multiple reactant traps 170 can be arranged in series, in parallel, or in a mixed configuration comprising both series and parallel arrangements. Multiple reactant traps 170 can enhance reactant capture.

In some embodiments, a system 100 as described herein can further comprise a purge gas recuperation unit 180 and a recuperated purge gas line 185. In some embodiments, the purge gas comprises at least one of N₂ and a noble gas. Suitable noble gasses can be selected from the list consisting of He, Ne, Ar, Kr, and Xe. The purge gas recuperation unit 180 can be constructed and arranged for recovering used purge gas from at least one of the reactant side stream and the precursor side stream, thereby obtaining a recuperated purge gas stream. The recuperated purge gas line 185 can be operationally connected to the purge gas recuperation unit 180 to the purge gas source, to recycle purge gas.

Indeed, by passing exhaust gases from the reaction chamber through one, or a series of precursor traps and/or reaction traps such as sorption units or cold traps, various by-products, e.g. condensable by-products, and unreacted precursors and reactants may be removed from the gas phase and collected for recycling or suitable disposal. The carrier gas which exits the one or more precursor traps may be of a purity high enough for reuse or recycling/upcycling (e.g. to run further processes or be used for nitrogen-fed vacuum pumps, for example. The purity of a gas stream such as a carrier gas stream can be monitored by means of in-line gas analyzers, for example.

Recycling inert gas streams such as carrier gasses may advantageously reduce carbon footprint associated with unnecessary loss of process gases to the waste stream, increase scrubber lifetime, and reduce the cost of tool operation by reducing argon/nitrogen costs. Indeed, in some systems, reaction chamber exhaust streams can be processed by scrubbers (which need regular replacement), before being released to the atmosphere as waste. Preventing this unnecessary loss of inert gasses such as argon and nitrogen is a huge potential source of carbon footprint and cost reduction. The resulting lower process gas requirements may also reduce tool footprint.

In some embodiments, the purge gas recuperation unit 180 is fluidly connected to the reactant trap 170. Thus, at least some of the purge gas passing through the reactant trap 170 can be recuperated in the purge gas recuperation unit 180. For example, this fluid connection can be accomplished by means of a reactant trap-purge gas recuperation unit line 172 that is provided with a corresponding check valve 173.

In some embodiments, the purge gas recuperation unit 180 is fluidly connected to the precursor trap 160. Thus, at least some of the purge gas passing through the precursor trap 160 can be recuperated in the purge gas recuperation unit 180. For example, this fluid connection can be accomplished by means of a precursor trap-purge gas recuperation unit line 162 that is provided with a corresponding check valve 163.

A system 100 according to the embodiment of FIG. 1 can comprise one or more pumps. For example, the system 100 can comprise a recuperated purge gas pump 189 which is provided on the recuperated purge gas line 185. The recuperated purge gas pump 189 and optional further pumps can advantageously provide the required pressure gradient for gas to flow through the system 100. In some embodiments, the system 100 according to the embodiment FIG. 1 further comprises a one or more of a precursor pump (not shown) and a reactant pump (not shown). The precursor pump can be constructed and arranged for pumping purified precursor to the precursor source 120. The reactant pump can be constructed and arranged for pumping purified reactant to the reactant source 130.

A system 100 according to the embodiment of FIG. 1 can comprise an exhaust line 190. The one or more exhaust line 190 can provide at least part of the recuperated purge gas stream to the atmosphere or to an abatement system. The exhaust line 190 can be in fluid connection with the recuperated purge gas line 185. The exhaust line 190 can comprise an exhaust valve 193, e.g. a check valve, that can be constructed and arranged for preventing back flow of contaminants such as atmospheric gasses into the system 100.

The recuperated purge gas line 185 can be provided with a recuperated purge gas valve 183 which can be any suitable valve. The recuperated purge gas valve 183 can be opened to allow purge gas recycling, or it can be closed to prevent purge gas recycling. The recuperated purge gas valve 183 can be provided on the recuperated purge gas line 185 downstream from the exhaust line 190.

In some embodiments, the reactant purification unit 177 can be operationally connected to the reactant source 130 by means of a purified reactant line 178 that is constructed and arranged to provide purified reactant from the reactant purification unit 177 to the reactant source 130. Suitably, the reactant purification unit 177 can comprise a pump (not shown) which is constructed and arrange to pump purified reactant from the reactant purification unit 177 to the reactant source 130.

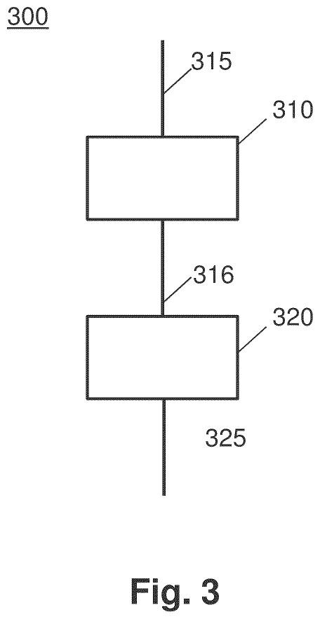

An embodiment of a purge gas recuperation unit 300 is described by reference to FIG. 3. In this embodiment, the purge gas recuperation unit 300 comprises a cold trap 310 and a sorption unit 320 in series which together can suitably purify a used purge gas stream carried by a used purge gas stream line 315 to form a purified purge gas stream carried by a purified purge gas stream line 325. The cold trap 310 can be operationally connected to the sorption unit 320 by means of a partially purified purge gas stream line 316. The purified purge gas stream 325 can be employed partially or wholly as a purge gas stream in a system according to an embodiment of the present disclosure. Additionally or alternatively, the purified purge gas stream 325 can be partially or wholly employed for a different purpose, e.g. as ballast gas in one or more pumps. It shall be noted that a cold trap may remove precursors and reaction by-products. Although such a system can be effective at removal of species having low vapor pressure at the temperature of the cold trap, it may be advantageous to remove reaction by-products that are gaseous up to low temperatures by different means. Indeed, gases such as CH₄, CO₂, CO, O₂ can be suitably removed using a different system such as a sorption trap. Suitable sorption traps can comprise porous adsorbent media which adsorbs gases that can be difficult to remove using cold traps.

In some embodiments, a purge gas recuperation unit as described herein can comprise one or more scrubbers. Advantageously, scrubbers can comprise a reactive medium that can react with at least one of the precursor and the reactant. Additionally or alternatively, a purge gas recuperation unit as described herein can comprise two or more scrubbers that can be arranged in series, in parallel, or in a mixed configuration. For example, a purge gas recuperation unit as described herein can comprise a reactant scrubber and a precursor scrubber arranged in series. For example, the reactant scrubber can be positioned upstream from the precursor scrubber. For example, the precursor scrubber can be positioned upstream from the reactant scrubber. The reactant scrubber can comprise a reactive medium that is constructed and arranged to react with the reactant. The precursor scrubber can comprise a reactive medium that is constructed and arranged to react with the precursor. One or more scrubbers can be used in addition to, or as an alternative of, one or more sorption traps.

It shall be noted that scrubbers and sorption traps as such are known in the art.

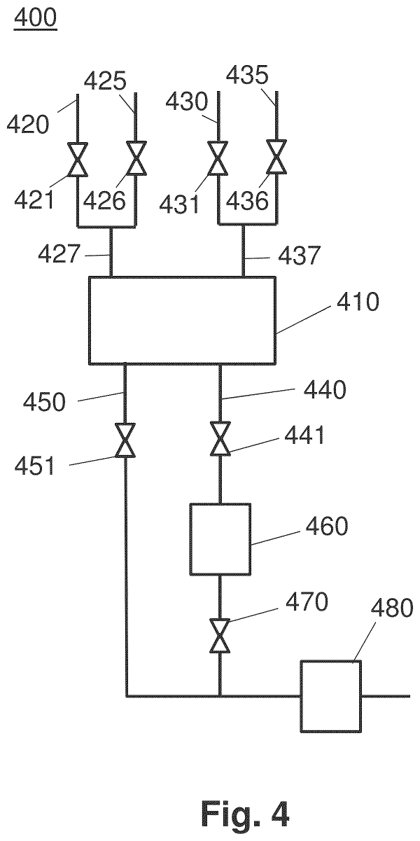

With reference to FIG. 4, described herein is an embodiment of a system 400 according to the present disclosure. The system 400 can be advantageously employed cyclical vapor phase processes such as atomic layer deposition, atomic layer etch, and plasma-enhanced variants thereof.

The system 400 comprises a precursor line 420 that is disposed with a precursor valve 421. The precursor valve 421 is constructed and arranged to open and close the precursor line 420. The system 400 further comprises a precursor purge gas line 425 that is disposed with a precursor purge gas valve 426. The precursor purge gas valve 426 is constructed and arranged to open and close the precursor purge gas line 425. The precursor line 420 and the precursor purge gas line 425 can merge into a joint precursor line 427 downstream from the precursor valve 421 and the precursor purge gas valve 426. The joint precursor line 427 is fluidly connected to a reaction chamber 410. In some embodiments, the joint precursor line 427 can be omitted in which case the precursor line 420 and the precursor purge gas line 425 can be in direct fluid connection with the reaction chamber 410.

The system 400 further comprises a reactant line 430 that is disposed with a reactant valve 431. The reactant valve 431 is constructed and arranged to open and close the reactant line 430. The system 400 further comprises a reactant purge gas line 435 that is disposed with a reactant purge gas valve 436. The reactant purge gas valve 436 is constructed and arranged to open and close the reactant purge gas line 435. The reactant line 430 and the reactant purge gas line 435 can merge into a joint reactant line 437 downstream from the reactant valve 431 and the reactant purge gas valve 436. The joint reactant line 437 is fluidly connected to a reaction chamber 410. In some embodiments, the joint reactant line 437 can be omitted in which case the reactant line 430 and the reactant purge gas line 435 can be in direct fluid connection with the reaction chamber 410.

As shown in the embodiment of FIG. 4, a system 400 as described herein can comprise separate exhaust lines 440,450 for precursor and reactant including a precursor exhaust line 440 and a reactant exhaust line 450. The precursor exhaust line 440 can be provided with a precursor exhaust valve 441. The reactant exhaust line 450 can be provided with a reactant exhaust valve 451. Downstream from the precursor exhaust valve 441, the precursor exhaust line 440 can be operationally connected to a precursor trap 460 as described herein. Downstream from the precursor trap 460, the precursor exhaust line 440 can be provided with a post precursor trap valve 470. Downstream from the reactant exhaust valve 451, the reactant exhaust line 450 can be in fluid connection with a pump 480. Similarly, downstream from the post precursor trap valve 470, the precursor exhaust line 440 can be in fluid connection with the pump 480. Exhaust from the pump 480 can be, for example, vented or sent to an abatement facility for treating reactant comprised in said exhaust.

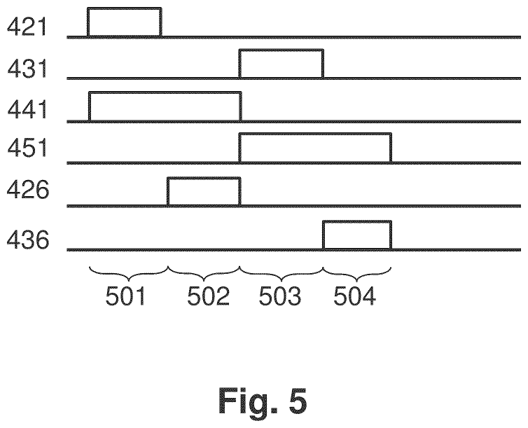

FIG. 5 shows an embodiment of a method for operating valves in a system 400 according to the embodiment of FIG. 4. In particular, FIG. 5 shows open and closed positions during a precursor pulse 501, a precursor purge 502, during a reactant pulse 503, and during a reactant purge 504.

The precursor valve 421 is initially open during the precursor pulse 501 and then closes during the precursor purge 502. The precursor purge gas valve 426 is initially closed during the precursor pulse 501 and then opens during the precursor purge 502. The precursor exhaust valve 441 is open during the precursor pulse 501 and the precursor purge 502. The reactant valve 431, the reactant purge gas valve 436, and the reactant exhaust valve 451 are closed during the precursor pulse 501 and the precursor purge 502.

The reactant valve 431 is initially open during the reactant pulse 503 and then closes during the reactant purge 504. The reactant purge gas valve 436 is initially closed during the reactant pulse 503 and then opens during the reactant purge 504. The reactant exhaust valve 451 is open during the reactant pulse 503 and the reactant purge 504. The precursor valve 421, the precursor purge gas valve 426, and the precursor exhaust valve 441 are closed during the reactant pulse 503 and the reactant purge 504. Thus, precursor can be captured efficiently in the precursor trap 460 while minimizing the amount of reactant captured in the precursor trap 460. This can be advantageous because it allows minimizing or eliminating unwanted side reactions between precursor and reactant in the precursor trap.

In some embodiments, precursor can be recuperated from the precursor trap 460. This can be done, for example, by isolating the precursor trap with valves, and replacing the trap with a new, empty trap. The filled trap can be shipped to a dedicated precursor purification facility for purifying the precursor using means which, as such, are known in the art.

Suitable precursors are known in the art. In some embodiments, precursors can comprise one or more metals such as transition metals, post transition metals, and rare earth metals. In some embodiments, a precursor comprises a group IV element such as silicon or germanium.

Suitable reactants can include one or more oxygen reactants, e.g. selected from H₂O, O₂, and O₃.

Suitable reactants can include one or more carbon reactants, e.g. selected from CO and CO₂.

Suitable reactants can include nitrogen reactants, e.g. selected from NH₃, N₂O, NO, NO₂, and NO₃.

Suitable reactants can include hydrogen reactants, e.g. H₂.

Suitable purge gasses can gasses such as N₂ and noble gasses. Suitable noble gasses can include He, Ne, Ar, Kr, and Xe.

It shall be understood that, in some embodiments, multiple systems as described can be comprised in a semiconductor processing facility. In such embodiments, the systems can be operationally connected to a central abatement facility. The central abatement facility can comprise at least one of one or more central purge gas purification units, one or more central precursor purification units, and central reactant purification units. At least one of the central purge gas purification units, the central precursor purification units, and the central reaction purification units can be operationally connected to more than one system as described herein. Thus, at least one of purge gas, precursor, and reactant from multiple systems can be purified by a single purification unit.

1. A system comprising:
a reaction chamber;
a precursor source comprising a precursor, the precursor source being operationally connected to the reaction chamber by means of a precursor line, the precursor line being disposed with a precursor valve that is operable to open and close the precursor line;
a reactant source comprising a reactant, the reactant source being operationally connected to the reaction chamber by means of a reactant line, the reactant line being disposed with a reactant valve that is operable to open and close the reactant line;
a precursor side stream line that is constructed and arranged to remove a precursor side stream from the reaction chamber, the precursor side stream line being disposed with a precursor side stream valve that is operable to open and close the precursor side stream line; and
a reactant side stream line that is constructed and arranged to remove a reactant side stream from the reaction chamber, the reactant side stream line being disposed with a reactant side stream valve that is operable to open and close the reactant side stream line.

2. The system according to claim 1, further comprising a controller, the controller comprising a memory containing computer-readable instructions which, when executed, cause the system to open the precursor line, close the reactant line, open the precursor side stream line, and close the reactant side stream line.

3. The system according to claim 1, further comprising a controller, the controller comprising a memory containing computer-readable instructions which, when executed, cause the system to open the reactant line, close the precursor line, open the reactant side stream line, and close the precursor side stream line.

4. The system according to claim 1, further comprising a controller, the controller comprising a memory containing computer-readable instructions which, when executed, cause the system to execute a cyclical deposition process, the cyclical deposition process comprising a plurality of cycles, ones from the plurality of cycles comprising a precursor pulse and a reactant pulse;
wherein the precursor pulse comprises opening the precursor line, closing the reactant line, opening the precursor side stream line, and closing the reactant side stream line, thereby providing the precursor to the reaction chamber and removing the precursor side stream from the reaction chamber via the precursor side stream line; and,
wherein the reactant pulse comprises opening the reactant line, closing the precursor line, opening the reactant side stream line, and closing the precursor side stream line, thereby providing the reactant to the reaction chamber and removing the reactant side stream from the reaction chamber via the reactant side stream line.

5. The system according to claim 4, further comprising a purge gas source comprising a purge gas, the purge gas source being operationally connected to the reaction chamber by means of a purge gas line, the purge gas line being disposed with one or more purge gas valves that are operable to open and close the purge gas line.

6. The system according to claim 5, wherein the cyclical deposition process further comprises a post precursor purge and a post reactant purge,
the post precursor purge being executed after the precursor pulse, wherein the post precursor purge comprises opening the purge gas line, opening the precursor side stream line, closing the precursor line, closing the reactant line, and closing the reactant side stream line; and
the post reactant purge being executed after the reactant pulse, wherein the post reactant purge comprises opening the purge gas line, opening the reactant side stream line, closing the precursor line, closing the reactant line, and closing the precursor side stream line.

7. The system according to claim 5, wherein the precursor side stream line is operationally connected to a precursor trap, the precursor trap being constructed and arranged for removing unreacted precursor from the precursor side stream.

8. The system according to claim 1, wherein the reactant side stream line is operationally connected to a reactant trap, the reactant trap being constructed and arranged for removing unreacted reactant from the reactant side stream.

9. The system according to claim 7, further comprising a purge gas recuperation unit, and a recuperated purge gas line,
the purge gas recuperation unit being constructed and arranged for recovering used purge gas from at least one of the reactant side stream and the precursor side stream, thereby obtaining a recuperated purge gas stream; and
the recuperated purge gas line operationally connecting the purge gas recuperation unit to the purge gas source, to recycle purge gas.

10. The system according to claim 9, wherein the purge gas comprises at least one of N₂, H₂, and a noble gas.

11. The system according to claim 7, wherein the precursor trap comprises a cold trap.

12. The system according to claim 11, further comprising a collection well constructed and arranged for holding unreacted precursor that was trapped by the cold trap.

13. The system according to claim 7, wherein the precursor trap comprises a sorption trap.

14. The system according to claim 7, further comprising a fractional distillation device, the fractional distillation device being constructed and arranged for purifying unreacted precursor from the precursor trap, thereby obtaining a purified precursor stream.

15. The system according to claim 14, wherein the fractional distillation device is operationally connected with the precursor source to provide at least a part of the purified precursor stream to the precursor source.
